(19) United States
(12) Patent Application Publication
(10) Pub. No.: US 2011/0173889 A1
(43) Pub. Date: Jul. 21, 2011

(54) DEVICE FOR DETECTING A BREAK-IN ATTEMPT ON AN OPENING MOVEABLY MOUNTED RELATIVE TO A FRAME

(76) Inventors: Alexandre Guichard, La Chapelle Du Mont Chat (FR); Bruno Bonnevie, Cognin (FR)

(21) Appl. No.: 12/376,409

(22) PCT Filed: Feb. 16, 2007
(86) PCT No.: PCT/FR2007/000195

§ 371 Date: Feb. 4, 2009

(51) Int. Cl. G08B 13/08; G01R 27/08

(52) U.S. Cl. 49/13; 324/693

(57) ABSTRACT

The invention relates to a device for detecting a break-in attempt on an opening (2) moveably mounted relative to a frame (3), characterised in that it comprises a sensor (4) connected to a supply and processing circuit, said sensor (4) including two electrically conductive layers between which an insulating layer is provided, each of the conductive layers being connected to an electric power supply, wherein said sensor (4) is to be inserted between the frame (3) and the opening (2).

The present invention relates to a device for detecting a break-in attempt experienced by an opening part mounted movably relative to a frame.

The invention relates more particularly to the use of such a device for a break-in attempt through an opening part mounted, for example, pivotably relative to a frame, such as an access door to a building or to an automobile, a roller shutter, a trapdoor, or others.

A certain number of devices suitable for allowing detection of a break-in experienced by an access door into a building are known. A number of these devices, especially those intended for private residences, are not satisfactory.

Thus, most of them can detect only break-ins that have already been performed; in other words, very specifically, when the opening part and/or its closing system is/are already open. Since, in such devices, the reaction time between the break-in that has already been performed and triggering of the alarm is not necessarily instantaneous, the intruder then has time to disconnect the alarm, or he can rapidly continue his break-in even after the alarm has been triggered, for example continue to intrude and burgle. It would thus be of interest to be able to detect a break-in attempt, i.e. any mechanical and/or thermal stress experienced by the opening part in its completely closed position in the frame, performed under abnormal utilization conditions characteristic of a break-in.

The purpose of the invention is thus to propose a device of the aforesaid kind at lower cost, the sensitivity of which allows detection of any break-in attempt experienced by the opening part before it is opened, and permits analysis of the type of break-in.

For that purpose, the object of the invention is a device for detecting a break-in attempt experienced by an opening part mounted movably relative to a frame. The solution according to the invention has a low installation cost, and exhibits a detection sensitivity with which the majority of break-ins usually observed on individual residence doors can be detected.

According to one characteristic of the invention, the device comprises electronic control means that are connected to electronic measurement means and are intended to control the threshold detected change value above which an alarm system is triggered. These control means can thus be actuated manually, or automatically by way of an electronic management system.

In practice, regulation of the change threshold for break-ins that generate mechanical vibrations could be programmed by the manufacturer of the detection device, while regulation of the change threshold for break-ins that generate impacts and are likely to be confused with loads on the opening part not relevant to a break-in (a person knocking on the door, etc.) could be effected manually by the end user.

The invention also relates to an opening part equipped with a detection device according to the invention for detecting a break-in attempt through an opening part mounted movably on a frame.

Other characteristics and advantages of the invention will emerge from the description that follows, with reference to the attached drawings that are provided only as non-limiting examples.

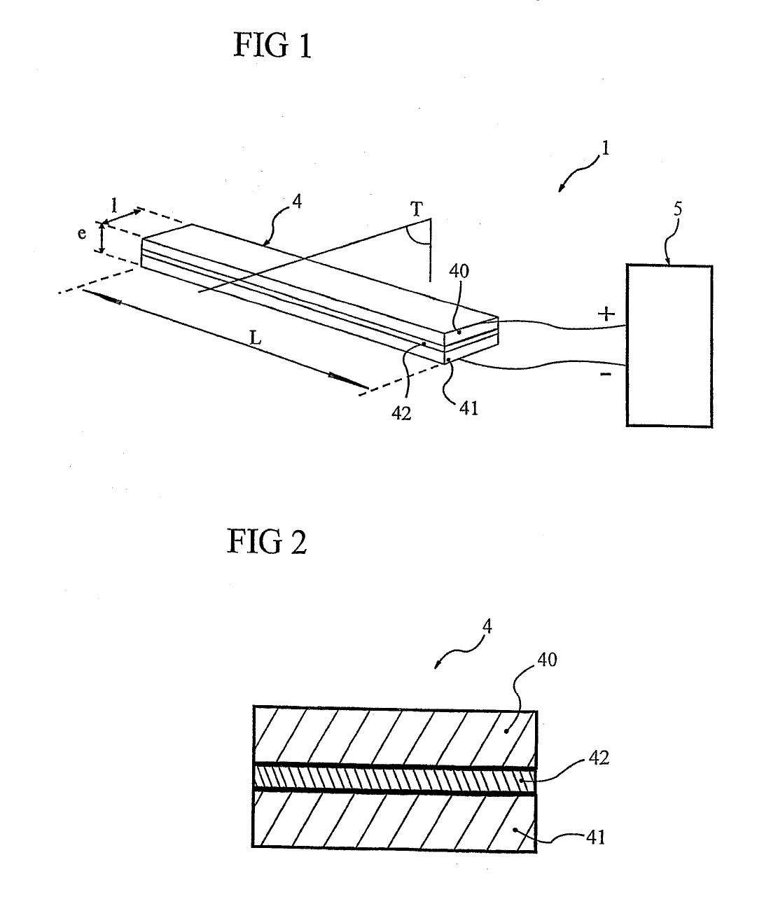

FIG. 1 is a perspective view of the detection device.

FIG. 2 is a cross-sectional view along the transverse plane (T) of the detection strip.

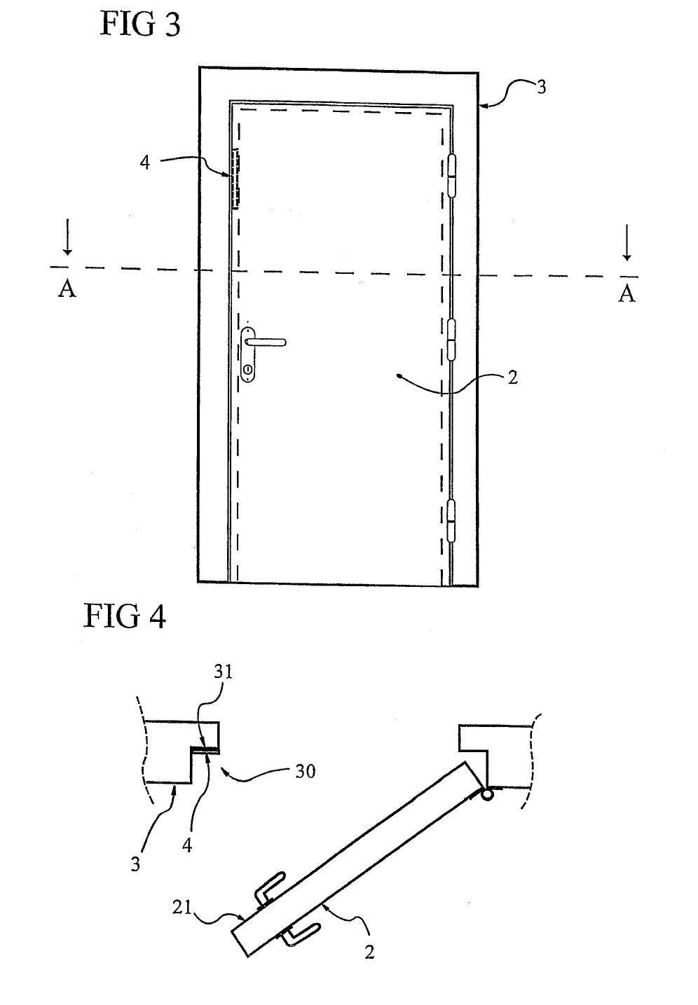

FIGS. 3 and 4 illustrate an installation example of the detection strip.

FIG. 3 is a front view of a door equipped with the detection strip according to the invention.

FIG. 4 is a horizontal section view of FIG. 3 along A-A at the level of the detection strip.

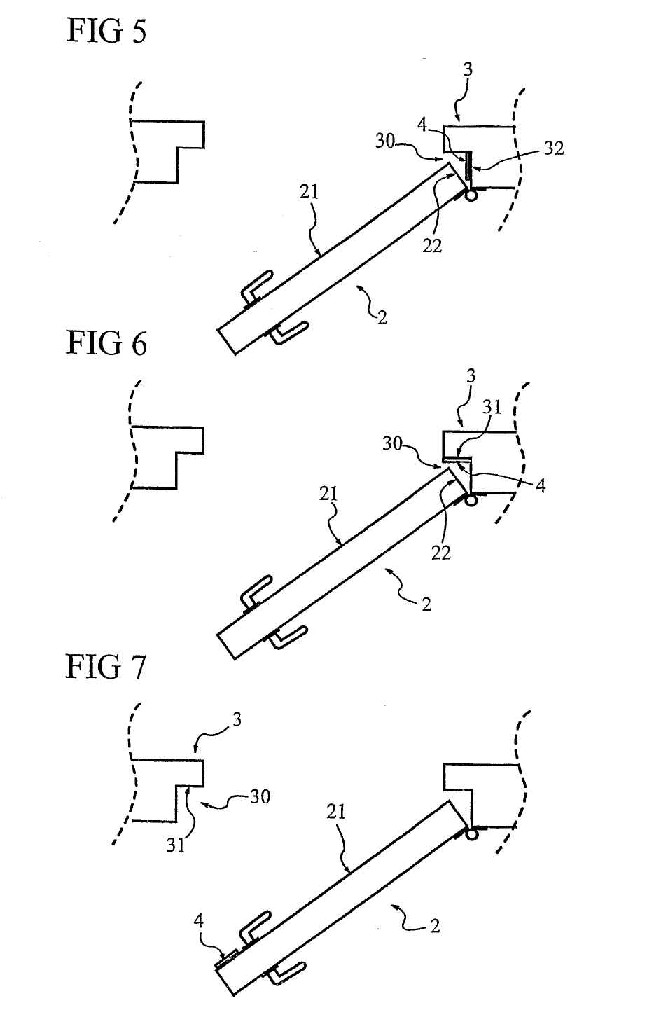

FIGS. 5 to 7 are schematic cross-sectional depictions showing three installation variants for the detection strip according to the invention.

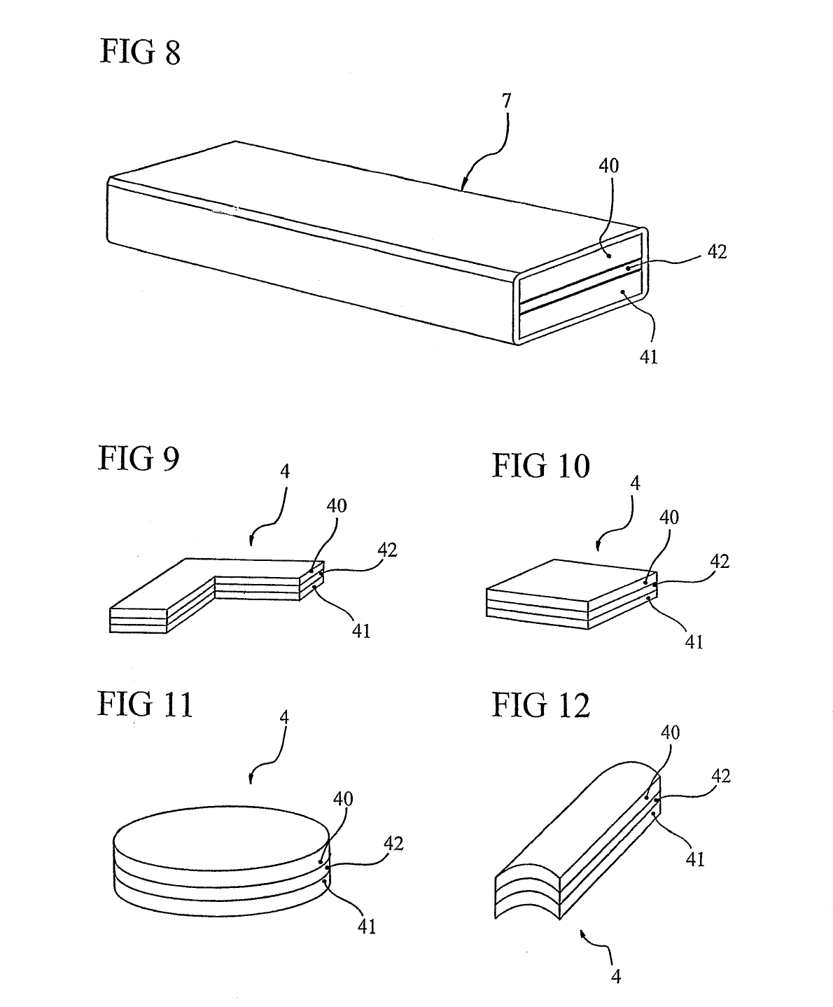

FIG. 8 is a perspective view of a variant embodiment of the detection strip according to which the latter is received in a sealing sheath.

FIGS. 9 to 12 are perspective views depicting variant embodiments of the sensor.

As illustrated, the detection device according to the invention, having the general reference character 1, is intended to detect any break-in attempt experienced by an opening part 2 mounted movably on a frame 3, such as an entrance door mounted pivotably relative to a frame 3 such as a door casing.

According to the embodiment depicted in FIGS. 1 to 8, detection device 1 comprises a sensor 4 made up of a rectilinear flat strip 4 extending longitudinally, made up of two electrically conductive layers 40, 41 in the shape of a flat sheet, between which is arranged an electrically insulating layer 42.

It is evident that flat strip 4 comprises two conductive layers 40, 41, made of an electrically conductive material, sandwiching between them an intermediate insulating layer 42 made of an electrically insulating material.

In addition, each of the conductive sheets 40, 41 is connected respectively to an electrical power and electrical measurement unit 5. With electrical power applied to each conductive sheet 40, 41, strip 4 with its intermediate insulating layer 42 thus behaves like a capacitor that is sensitive to any physical change in its structure. Bringing conductive layers 40, 41 closer together, and/or then establishing an electrical bridge between those sheets, modifies the resistance or capacitance value of detection strip 4.

Detection of a change in those values is then utilized to generate a datum.

During a break-in attempt, the change in the resistance and/or capacitance of sensor 4 then generates an electrical datum to a control unit that actuates the security system.

Conductive layers 40, 41 made of conductive material can be implemented with a plastic or thermoset resin containing a filling or a conductive agent.

The resins usable can be any thermoset resins, for example polyester or epoxies, or any thermoplastic resins, for example polyethylene, polypropylene, polyamide, or PET.

The conductive-agent filling can be made of graphite, carbon, metal powders, or carbon nanotubes, or even glass, chalk, or any other agent that can ensure and modulate conductivity.

Intermediate insulating layer 42 is an electrical insulator that advantageously is polarizable, i.e. has dielectric properties. The insulating layer can thus be of any type, for example realized by way of a simple coat of paint applied under one or other of sheet 40, 41 or under both.

Also noteworthy is the fact that detection strip 4 is flat and extends in rectilinear fashion; while its length L is between 2 centimeters and 2 meters, it is advantageously between 5 centimeters and 50 centimeters.

Detection strip 4 has a width l between 5 and 30 millimeters, while its thickness e is between 1 and 10 millimeters.

Each of the conductive strips 40, 41 is connected to an electrical power source and to a processing unit 5.

Strip 4 is intended to be inserted between frame 3 and the corresponding opening part 2. For that purpose, strip 4 is fastened either onto a portion of frame 3 facing toward opening part 2, or onto a portion of opening part 2 facing toward frame 3.

Various ways of installing detection strip 4 according to the invention are illustrated in FIGS. 3 to 7.

Detection strip 4 is fastened, for example, using adhesive or the like, for example double-faced adhesive tape, which is adhered onto the external surface of the conductive sheet that is required to be in contact with the support (stationary or opening part).

According to the approaches to installing detection strip 4 illustrated in FIGS. 4 to 6, said strip is fastened by adhesive bonding onto opening part 3 inside rabbet 30.

According to the implementation of FIGS. 3 and 4, detection strip 4 is fastened in rabbet 30 of the lateral upright of the frame on the opening side, on front edge 31 of rabbet 30 facing toward the corresponding surface 21 of opening part 2.

Detection strip 4, having e.g. a length from 5 to 20 centimeters, is fastened onto the top part as depicted in FIG. 3. Detection strip 4 could of course be installed at other locations without thereby leaving the scope of the invention.

According to the implementation of FIG. 5, detection strip 4 is fastened onto the lateral upright of frame 3 on the hinge side, on lateral edge 32 that faces toward the corresponding end face 22 of opening part 2.

According to the implementation of FIG. 6, detection strip 4 is fastened in rabbet 30 of the lateral upright of the frame on the hinge side, on front edge 31 of rabbet 30 that faces toward the corresponding surface 21 of opening part 2.

FIG. 7 illustrates another variant in which the detection strip is arranged on opening part 2 facing toward frame 3. In this instance, detection strip 4 is fastened onto face 21 of opening part 2 facing toward frame 3.

FIG. 8 is a perspective view of a variant embodiment of detection strip 4, according to which the latter is received in a sealing sheath 7 made of flexible plastic material or of another deformable flexible material such as, for example, rubber or the like.

As illustrated in FIG. 1, device 1 according to the invention comprises an electrical power and processing unit 5 intended to process the signals transmitted by detection strip 4. This unit 5 thus comprises electronic control means connected to electronic measurement means and intended to regulate the threshold detected change value above which an alarm system is triggered. The alarm system can be of any type: acoustic, visual, connected to a central security system, etc.

Relative displacement of one of the conductive sheets 40, 41 relative to the other, or establishment of an electrical bridge between said sheets 40, 41, instantaneously modifies the resistive and capacitative values of detection strip 4.

During a break-in attempt, the change in the capacitance and resistance of detection strip 4 thus generates an electrical signal to the measurement means, which actuates the alarm system in the event the preprogrammed change threshold(s) is/are exceeded.

It is evident that by means of processing unit 5, which receives the data received from detection strip 4 and especially the changes in the capacitance thereof, it is possible to analyze and determine, by parameterization of the electronic system, the type of break-in involved; to associate an electrical signal with a specific type of event (puncture, shoulder impact, use of a crowbar, etc.); and thus to effect, in response, an appropriate action, for example triggering an alarm, a telephone call, emission of a liquid or a gas, etc.).

The invention is of course not limited to the embodiments that are described and depicted by way of example, but also encompasses all technical equivalents as well as combinations thereof.

Sensor 4 depicted in FIGS. 1 to 7 and described above is thus constituted by a rectilinear strip, but it could also be different as illustrated in FIGS. 8 to 11.

According to the variant of FIG. 9, sensor 4 exists in the form of an angle bracket, which can be installed e.g. in the angle of a stationary or opening part.

According to the variant of FIG. 10, sensor 4 is shaped like a square rather than a strip.

According to the variant of FIG. 11, sensor 4 is shaped like a disk rather than a strip.

According to the variant of FIG. 12, the sensor exists in the form of a detection strip but its section is curved rather than flat.

1. A device for detecting a break-in attempt (1) experienced by an opening part (2) mounted movably relative to a frame (3), comprising:
a sensor (4) connected to a power supply and processing circuit (5), said sensor (4) being constituted by two electrically conductive layers (40, 41) between which is arranged an electrically insulating layer (42) while each of the conductive layers is connected to an electrical power source, said sensor (4) being intended to be inserted between the frame (3) and the opening part (2).

2. The device for detecting a break-in attempt (1) experienced by an opening part (2) mounted movably relative to a frame (3), according to claim 1, wherein the sensor (4) is fastened onto a portion of the frame (3) facing toward the opening part (2).

3. The device for detecting a break-in attempt (1) experienced by an opening part (2) mounted movably relative to a frame (3), according to claim 1, wherein the sensor (4) is fastened onto a portion of the opening part (2) facing toward the frame (3).

4. The device for detecting a break-in attempt (1) experienced by an opening part (2) mounted movably relative to a frame (3), according to claim 3, wherein the sensor (4) is fastened in the rabbet (30) of the frame (3).

5. The detection device (1) according to claim 4, wherein the conductive layers (40, 41) made of conductive material are implemented with a plastic or thermoset resin comprising a filling or a conductive agent.

6. The detection device (1) according to claim 5, wherein the resin is a thermoset resin, for example polyester or epoxies, or any thermoplastic resins, for example polyethylene, polypropylene, polyamide, or PET.

7. The detection device (1) according to claim 6, wherein the conductive agent is graphite or carbon or a metal powder, or carbon nanotubes, glass, chalk, or any other agent that can ensure and modulate conductivity.

8. The detection device (1) according to claim 7, wherein the sensor (4) exists in the form of a flat and rectilinear detection strip, while the conductive layers are constituted by two flat sheets (40, 41).

9. The detection device (1) according to claim 1, wherein the sensor (4) has a length (L) of between 2 centimeters and 2 meters.

10. The detection device (1) according to claim 9, wherein the sensor (4) has a width (l) of between 5 and 30 millimeters.

11. The detection device (1) according to claim 10, wherein the sensor (4) has a thickness (e) of between 1 and 10 millimeters.

12. The detection device (1) according to claim 8, wherein the detection strip (4) is received in a sealing sheath (7) made of flexible plastic material or of another deformable flexible material such as, for example, rubber or the like.

13. An opening part (2) mounted movably on a frame (3) equipped with the detection device according to claim 1, wherein the sensor (4) is arranged between the opening part and the frame.
